(19) United States
(12) Patent Application Publication
(10) Pub. No.: US 2025/0380568 A1
(43) Pub. Date: Dec. 11, 2025

(54) DISPLAY APPARATUS

(71) Applicant: Samsung Display Co., Ltd., Yongin-si (KR)

(72) Inventors: Kangmoon JO, Yongin-si (KR); Donghyeon KI, Yongin-si (KR); Sunkwang KIM, Yongin-si (KR); Inyoung SON, Yongin-si (KR); Seongyoung LEE, Yongin-si (KR); Sanguk LIM, Yongin-si (KR)

(73) Assignee: Samsung Display Co., Ltd., Yongin-si (KR)

(21) Appl. No.: 19/066,652

(22) Filed: Feb. 28, 2025

(30) Foreign Application Priority Data
Jun. 7, 2024 (KR) 10-2024-0074575

(51) Int. Cl. H10K 59/121; H10K 59/131; H10K 59/38

(52) U.S. Cl. CPC H10K 59/1213; H10K 59/131; H10K 59/38

(57) ABSTRACT

A display apparatus includes a bottom metal layer including a power line and a data line each of which extends in a first direction, an active layer disposed over the bottom metal layer and including a semiconductor material, a gate layer disposed over the active layer and including gate electrodes each of which overlaps a portion of the active layer, a first source-drain layer disposed over the gate layer and including a scan line extending in a second direction intersecting the first direction, a second source-drain layer disposed over the first source-drain layer and including a common voltage line having a portion extending in the first direction and a portion extending in the second direction, and a pixel electrode layer disposed over the second source-drain layer and including a pixel electrode.

### CROSS-REFERENCE TO RELATED APPLICATION(S)

This application claims priority to and benefits of Korean Patent Application No. 10-2024-0074575 under 35 U.S.C. § 119, filed on Jun. 7, 2024 in the Korean Intellectual Property Office, the entire contents of which are herein incorporated by reference.

### BACKGROUND

### 1. Technical Field

One or more embodiments relate to a display apparatus in which a high-quality image may be displayed with a high aperture ratio.

### 2. Description of the Related Art

In general, display apparatuses such as organic light-emitting display apparatuses may include thin-film transistors, connection electrodes, and wirings that are arranged in each subpixel to control the luminance of each subpixel. The thin-film transistors, connection electrodes, and wirings may form a multilayer structure.

### SUMMARY

However, display apparatuses of the related art may have unintended luminance non-uniformity or may have defects during a manufacturing process.

One or more embodiments include a display apparatus in which a high-quality image may be displayed with a high aperture ratio. However, the above aspect is just an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus may include a bottom metal layer including a power line and a data line each of which extends in a first direction, an active layer disposed over the bottom metal layer and including a semiconductor material, a gate layer disposed over the active layer and including gate electrodes each of which overlaps a portion of the active layer, a first source-drain layer disposed over the gate layer and including a scan line extending in a second direction intersecting the first direction, a second source-drain layer disposed over the first source-drain layer and including a common voltage line having a portion extending in the first direction and a portion extending in the second direction, and a pixel electrode layer disposed over the second source-drain layer and including a pixel electrode.

The portion of the common voltage line which extends in the first direction and the portion of the common voltage line which extends in the second direction may be integral with each other.

The common voltage line may have a mesh shape in a plan view.

The active layer may include a first active layer and a second active layer which are spaced apart from each other, the gate electrodes may include a first gate electrode and a second gate electrode, the first gate electrode overlapping a portion of the first active layer, and the second gate electrode extending in the first direction and overlapping a portion of the second active layer, the first source-drain layer may include a transistor connection layer and a capacitor electrode, the transistor connection layer electrically connecting the second active layer and the first gate electrode to each other, and the capacitor electrode overlapping the first gate electrode, and the second source-drain layer may include a pixel electrode connection layer located within the common voltage line having the mesh shape in the plan view.

The pixel electrode connection layer may overlap the transistor connection layer in the plan view.

The transistor connection layer may be located in the pixel electrode connection layer within the plan view.

The first gate electrode may be located within a set of the capacitor electrode and the pixel electrode connection layer in the plan view.

The pixel electrode connection layer may be electrically connected to the capacitor electrode.

The first gate electrode may be located within a set of the capacitor electrode and the pixel electrode connection layer in the plan view.

The pixel electrode connection layer may contact the capacitor electrode through a contact hole.

The first gate electrode may be located within a set of the capacitor electrode and the pixel electrode connection layer in the plan view.

The pixel electrode may contact the pixel electrode connection layer through a contact hole.

The pixel electrode layer may include common electrode connection layers each of which is electrically connected to the common voltage line.

Each of the common electrode connection layers may contact the common voltage line through a contact hole.

Each of the common electrode connection layers may contact a common electrode disposed over the pixel electrode.

The common electrode connection layers may correspond to through holes defined in a pixel-defining film covering an edge of the pixel electrode.

In pixels located in a first row extending in the second direction, the common electrode connection layers may be located to correspond to odd-numbered pixels.

The second source-drain layer may include a pixel electrode connection layer. In a blue subpixel, the pixel electrode may have a first end adjacent to a corresponding one of the common electrode connection layers and a second end facing away from the corresponding one of the common electrode connection layers, a contact hole through which the pixel electrode contacts the pixel electrode connection layer being located at the second end.

In pixels located in a second row adjacent to the first row and extending in the second direction, the common electrode connection layers may be located to correspond to even-numbered pixels.

The second source-drain layer may include a pixel electrode connection layer. In a blue subpixel, the pixel electrode may have a first end adjacent to a corresponding one of the common electrode connection layers and a second end facing away from the corresponding one of the common electrode connection layers, a contact hole through which the pixel electrode contacts the pixel electrode connection layer being located at the second end.

Other aspects, features, and advantages will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view illustrating a portion of a display apparatus according to an embodiment;

FIG. 2 is a schematic diagram illustrating a portion of the display apparatus of FIG. 1;

FIG. 3 is a schematic diagram of an equivalent circuit illustrating a display element included in the display apparatus of FIG. 1 and a pixel circuit connected to the display element;

FIG. 4 is a schematic view illustrating locations of transistors and a storage capacitor in one pixel included in the display apparatus of FIG. 1;

FIGS. 5 to 10 are schematic views illustrating components, such as the transistors and the storage capacitor, of the display apparatus illustrated in FIG. 4 for each layer;

FIG. 11 is a schematic cross-sectional view illustrating a cross-section of the display apparatus taken along line A-A′ of FIG. 4; and

FIGS. 12 and 13 are schematic views illustrating components in multiple pixels for each layer.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the following embodiments, when an element, such as a layer, a film, a region, or a plate, is referred to as being “on” another element, the element can be directly on the other element, or intervening elements may be present therebetween. Also, sizes of elements in the drawings may be exaggerated or reduced for convenience of description. For example, because sizes and thicknesses of elements in the drawings may be arbitrarily illustrated for convenience of description, the following embodiments are not limited thereto.

In the following embodiments, the x-axis, the y-axis, and the z-axis may not be limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiments, while terms such as “first” and “second” are used to describe various elements, these elements are not limited by these terms. These terms are only used to distinguish one element from another element.

In the following embodiments, terms such as “include,” “comprise,” and “have” specify the presence of stated features or elements, but do not preclude the presence or addition of one or more other features or elements.

In the following embodiments, when a layer, region, or element is referred to as being “connected to” another layer, region, or element, it can be directly or indirectly connected to the other layer, region, or element. That is, for example, intervening layers, regions, or elements may be present. For example, when a layer, region, or element is referred to as being “electrically connected to” or “electrically coupled to” another layer, region, or element, it can be directly or indirectly electrically connected or coupled to the other layer, region, or element. That is, for example, intervening layers, regions, or elements may be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

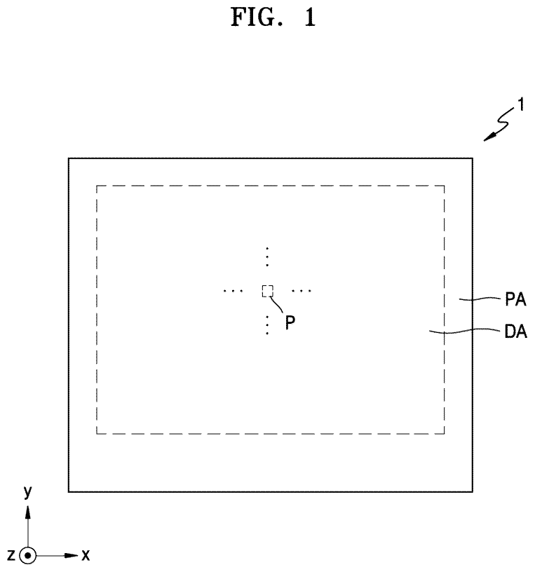

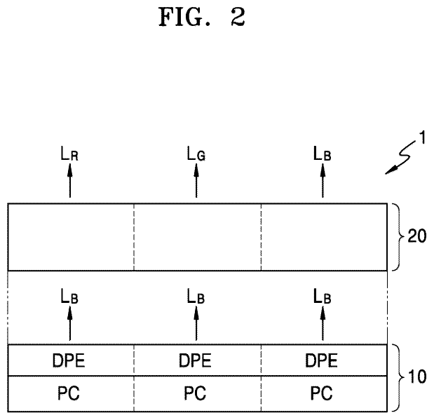

FIG. 1 is a schematic plan view illustrating a portion of a display apparatus 1 according to an embodiment, and FIG. 2 is a schematic diagram illustrating a portion of the display apparatus 1 of FIG. 1.

As illustrated in FIG. 1, the display apparatus 1 may include a display area DA in which multiple pixels P are arranged and a peripheral area PA located outside the display area DA. The peripheral area PA may entirely surround the display area DA.

As illustrated in FIG. 1, the display area DA may have a polygonal shape including a quadrangular shape. For example, the display area DA may have a rectangular shape having a horizontal length greater than a vertical length, a rectangular shape having a horizontal length less than a vertical length, or a square shape. In other embodiments, the display area DA may have various shapes, such as a polygonal shape other than a rectangular shape, an elliptical shape, or a circular shape.

As illustrated in FIG. 2, the display apparatus 1 may include a light-emitting panel 10 and a filter panel 20 which is stacked on the light-emitting panel 10. The light-emitting panel 10 may include multiple display elements DPE, and each of the display elements DPE may be electrically connected to a circuit PC (hereinafter, referred to as a pixel circuit). The display elements DPE and the pixel circuits PC may be arranged in the display area DA.

The display area DA may provide a certain image by using light from the display elements DPE. Blue light L_{B} emitted from the display elements DPE may be converted into red light L_{R} and green light L_{G} while passing through the filter panel 20, or may be transmitted through the filter panel as is without being converted. For example, the filter panel 20 may include a quantum dot layer so that the blue light L_{B} in a red subpixel may be converted into the red light L_{R} by the quantum dot layer and extracted to the outside, the blue light L_{B} in a green subpixel may be converted into the green light L_{G} by the quantum dot layer and extracted to the outside, and the blue light L_{B} in a blue subpixel may be extracted to the outside as is without being converted. The filter panel 20 may include a light-transmitting layer in a portion corresponding to the blue subpixel. The display apparatus 1 may provide a certain image by using light, such as the red light L_{R}, the green light L_{G}, and the blue light L_{B}, that is converted by the filter panel 20 or transmitted through the filter panel without being converted.

The peripheral area PA may be a non-display area that does not provide an image and may entirely surround the display area DA. A driver or main power line may be arranged in the peripheral area PA to provide electrical signals or power to the pixel circuits PC. A pad to which an electronic element or printed circuit board may be electrically connected may be arranged in the peripheral area PA.

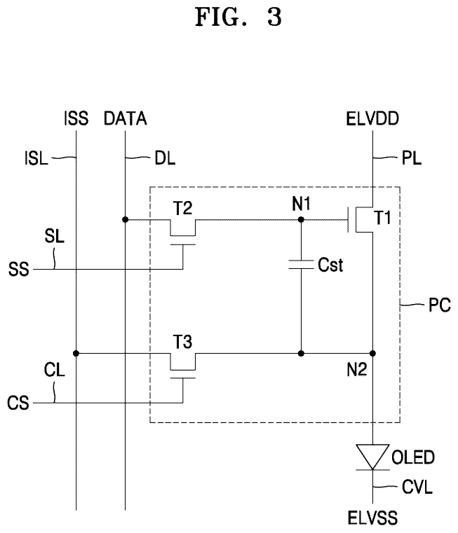

FIG. 3 is a schematic diagram of an equivalent circuit illustrating the display element DPE included in the display apparatus 1 of FIG. 1 and the pixel circuit PC connected to the display element DPE. That is, FIG. 3 is a diagram illustrating the display element DPE and the pixel circuit PC connected thereto, which correspond to one subpixel among subpixels included in one pixel of the display apparatus 1. FIG. 3 illustrates that an organic light-emitting diode OLED as the display element DPE is electrically connected to the pixel circuit PC. In detail, a pixel electrode of the organic light-emitting diode OLED may be electrically connected to the pixel circuit PC, and a counter electrode of the organic light-emitting diode OLED may be electrically connected to a common voltage line CVL configured to provide a common power voltage ELVSS. The organic light-emitting diode OLED may emit light with a luminance corresponding to the amount of current supplied from the pixel circuit PC.

The pixel circuit PC may include a first transistor T1, a second transistor T2, a third transistor T3, and a storage capacitor Cst. Each of the first transistor T1, the second transistor T2, and the third transistor T3 may be an oxide semiconductor thin-film transistor including a semiconductor layer made of an oxide semiconductor, or may be a silicon semiconductor thin-film transistor including a semiconductor layer made of polysilicon. FIG. 3 illustrates that each of the first transistor T1, the second transistor T2, and the third transistor T3 is an n-channel metal-oxide semiconductor (NMOS) transistor, but the disclosure is not limited thereto. For example, each of the first transistor T1, the second transistor T2, and the third transistor T3 may be a p-channel metal-oxide semiconductor (PMOS) transistor. In other embodiments, some of the first transistor T1, the second transistor T2, and the third transistor T3 may be NMOS transistors, and the rest may be PMOS transistors.

The first transistor T1 may be a driving transistor. An end of the first transistor T1 may be electrically connected to the pixel electrode of the organic light-emitting diode OLED, and another end of the first transistor T1 may be electrically connected to a power line PL configured to supply a driving power voltage ELVDD. A driving gate electrode of the first transistor T1 may be electrically connected to a first node N1. The first transistor T1 may control the amount of current flowing from the power line PL to the organic light-emitting diode OLED, in response to a voltage of the first node N1.

The second transistor T2 may be a switching transistor. An end of the second transistor T2 may be electrically connected to a data line DL, and another end of the second transistor T2 may be electrically connected to the first node N1. A switching gate electrode of the second transistor T2 may be electrically connected to a scan line SL. In case that a scan signal SS is supplied to the scan line SL, the second transistor T2 may be turned on to electrically connect the data line DL and the first node N1 to each other so that a data signal DATA from the data line DL may be transmitted to the first node N1.

The third transistor T3 may be an initialization-sensing transistor. An end of the third transistor T3 may be electrically connected to an initialization-sensing line ISL, and another end of the third transistor T3 may be electrically connected to a second node N2. An initialization gate electrode of the third transistor T3 may be electrically connected to a control line CL. In other embodiments, the initialization gate electrode of the third transistor T3 may be electrically connected to the scan line SL, like the switching gate electrode of the second transistor T2.

In case that a control signal CS is supplied to the control line CL, the third transistor T3 may be turned on to electrically connect the initialization-sensing line ISL and the second node N2 to each other so that an initialization-sensing signal ISS from the initialization-sensing line ISL may be transmitted to the second node N2. For example, in case turned on, the third transistor T3 may initialize an electric potential of the pixel electrode of the organic light-emitting diode OLED by using the initialization-sensing signal ISS from the initialization-sensing line ISL as an initialization voltage. In other embodiments, in case turned on, the third transistor T3 may sense characteristic information of the organic light-emitting diode OLED. As such, the third transistor T3 may function as both an initialization transistor and a sensing transistor, or may function as any one of such transistors. In case that the third transistor T3 functions as an initialization transistor, the initialization-sensing line ISL may be considered an initialization voltage line, and in case that the third transistor T3 functions as a sensing transistor, the initialization-sensing line ISL may be considered a sensing line. An initialization operation and a sensing operation of the third transistor T3 may be performed separately or simultaneously. In other words, the third transistor T3 may be an initialization transistor and/or a sensing transistor. Hereinafter, for convenience of description, a case where the third transistor T3 functions as both an initialization transistor and a sensing transistor is described.

The storage capacitor Cst may be connected between the first node N1 and the second node N2. For example, a capacitor electrode of the storage capacitor Cst may be electrically connected to a gate electrode of the first transistor T1, and another capacitor electrode of the storage capacitor Cst may be electrically connected to the pixel electrode of the organic light-emitting diode OLED.

FIG. 3 illustrates that the pixel circuit PC included in one subpixel includes three transistors, that is, the first to third transistors T1 to T3, and one storage capacitor Cst, but the disclosure is not limited thereto. For example, the number of transistors or storage capacitors included in the pixel circuit PC may be variously changed.

FIG. 3 illustrates a case where the display element DPE is an organic light-emitting diode OLED including an organic material, but the disclosure is not limited thereto. For example, the display element DPE may be an inorganic light-emitting diode including an inorganic material. The inorganic light-emitting diode may include a PN junction diode including inorganic material semiconductor-based materials. In case that a voltage is applied to the PN junction diode in a forward direction, holes and electrons may be injected, and energy generated by recombination of the holes and electrons may be converted into light energy to emit light of a certain color. The inorganic light-emitting diode may have a width of several micrometers to several hundreds of micrometers. The inorganic light-emitting diode may be referred to as a micro light-emitting diode (LED).

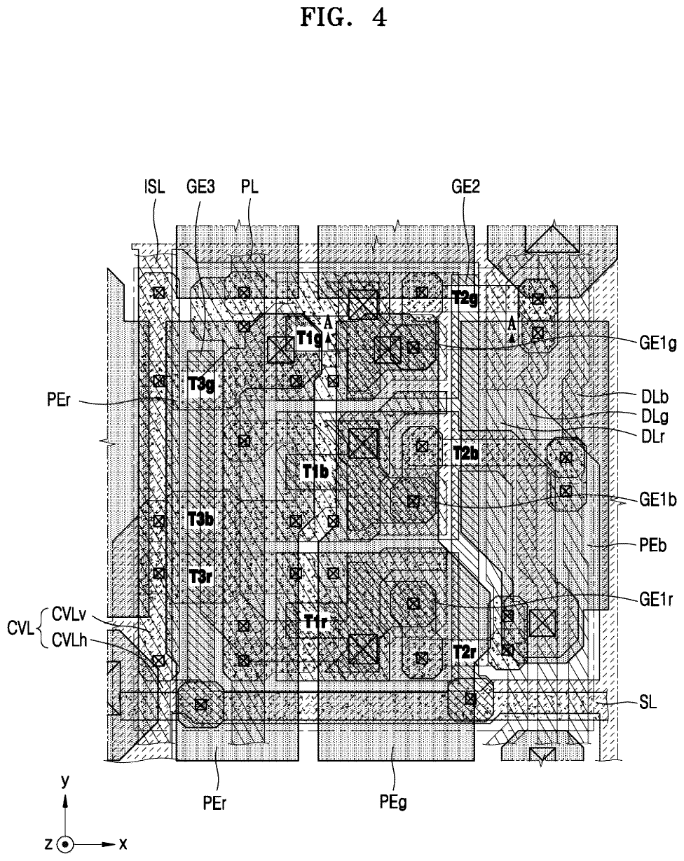

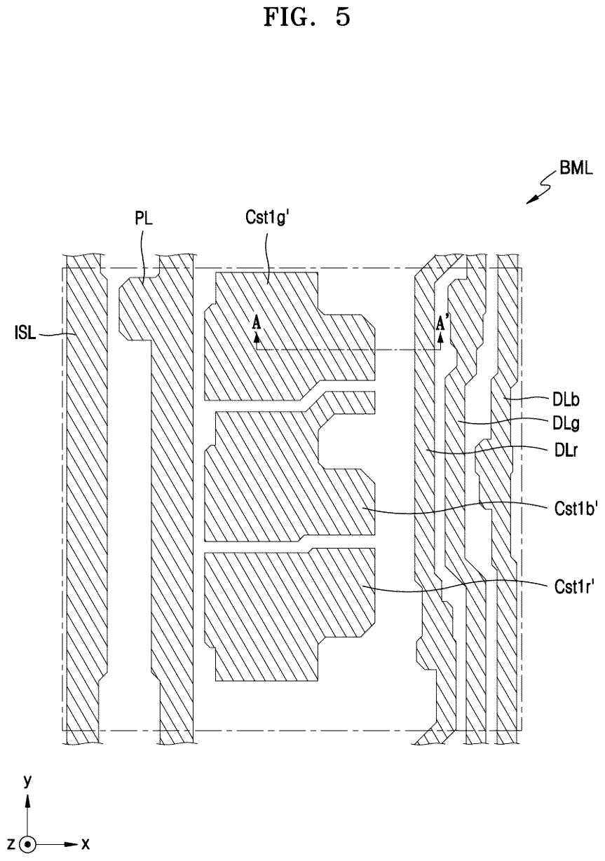

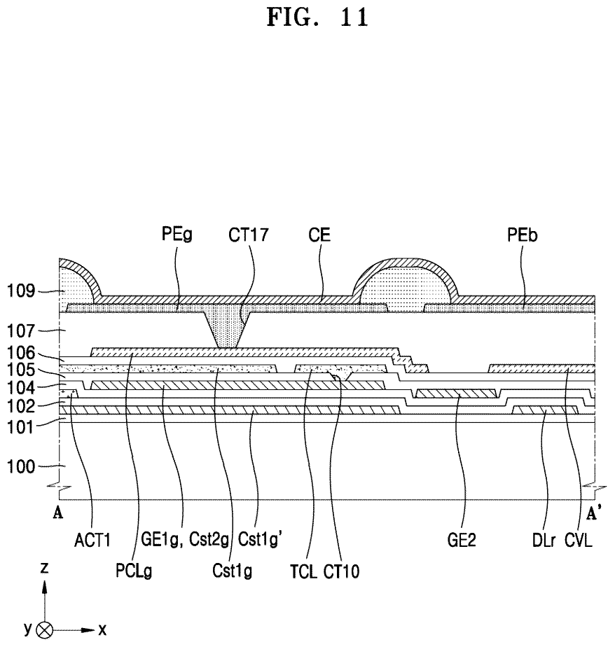

FIG. 4 is a schematic view illustrating locations of transistors and storage capacitors Cst in one pixel included in the display apparatus 1 of FIG. 1, FIGS. 5 to 10 are schematic views illustrating components, such as the transistors and the storage capacitors Cst, of the display apparatus 1 illustrated in FIG. 4 for each layer, and FIG. 11 is a schematic cross-sectional view illustrating a cross-section of the display apparatus 1 taken along line A-A′ of FIG. 4.

As described above, one pixel may include multiple subpixels, for example, three subpixels. Thus, the equivalent circuit diagram of FIG. 3 described above is an equivalent circuit diagram of one subpixel. FIG. 4 schematically illustrates locations of transistors and storage capacitors Cst in one pixel including three subpixels.

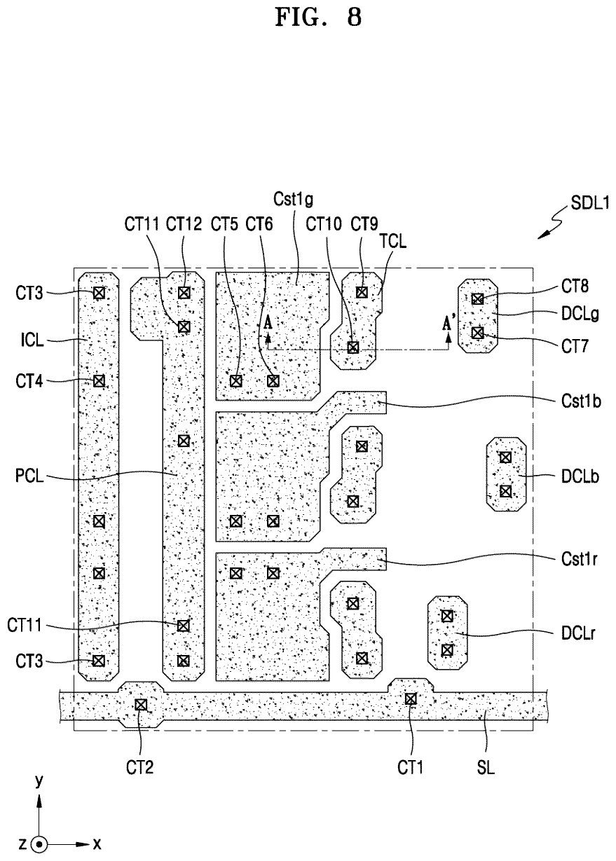

As illustrated in the drawings, one pixel may include three subpixels. FIG. 4 illustrates a case where one pixel includes a red subpixel, a green subpixel, and a blue subpixel. The red subpixel may include one storage capacitor Cst including a first capacitor electrode Cst1r (see FIG. 8) and three transistors, that is, first to third transistors T1r, T2r, and T3r, the green subpixel may include one storage capacitor Cst including a first capacitor electrode Cst1g (see FIG. 8) and three transistors, that is, first to third transistors T1g, T2g, and T3g, and the blue subpixel may include one storage capacitor Cst including a first capacitor electrode Cst1b (see FIG. 8) and three transistors, that is, first to third transistors T1b, T2b, and T3b. Components of the green subpixel and components of the blue subpixel may be identical and/or similar to components of the red subpixel. Hereinafter, for convenience of description, the components of the green subpixel are described, and the following description may also be applied to the components of the red subpixel and the components of the blue subpixel.

The display apparatus 1 may include a substrate 100 (see FIG. 11), and various components, such as the first to third transistors T1g, T2g, and T3g and the storage capacitors Cst, may be disposed over the substrate 100. The substrate 100 may include glass, metal, or polymer resin. In case that the substrate 100 is flexible or bendable, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may be variously modified. For example, the substrate 100 may have a multilayer structure including two layers each including the above polymer resin and a barrier layer arranged between the two layers and including an inorganic material, such as silicon oxide, silicon nitride, or silicon oxynitride.

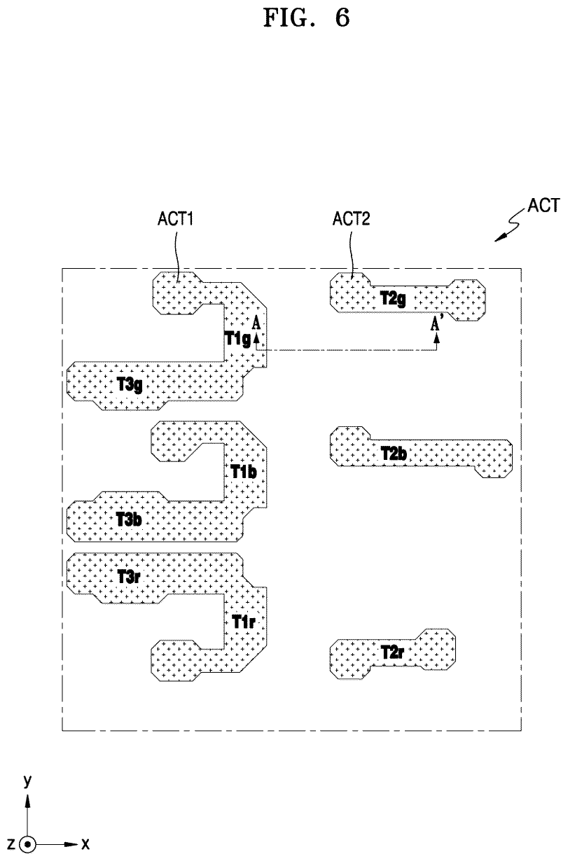

A first buffer layer 101 (see FIG. 11) including an inorganic insulating material, such as silicon oxide, silicon nitride, silicon oxynitride, or aluminum oxide, may be disposed over the substrate 100. The first buffer layer 101 may prevent metal atoms or impurities from diffusing from the substrate 100 to an active layer ACT (see FIG. 6) located above the first buffer layer 101.

A bottom metal layer BML as illustrated in FIG. 5 may be disposed over the first buffer layer 101. The bottom metal layer BML may include various signal lines and may overlap at least a portion of the active layer ACT located above the bottom metal layer BML to protect the active layer ACT including a semiconductor material. In case that the active layer ACT includes polysilicon, the bottom metal layer BML may control the rate at which heat is provided to an amorphous silicon layer during a crystallization process for forming the active layer ACT so that the active layer ACT may be uniformly crystallized. The bottom metal layer BML may include a metal, an alloy, a conductive metal oxide, or a transparent conductive material. For example, the bottom metal layer BML may include silver (Ag), an Ag-containing alloy, molybdenum (Mo), an Mo-containing alloy, aluminum (Al), an Al-containing alloy, aluminum nitride (AlN), tungsten (W), tungsten nitride (WN), copper (Cu), nickel (Ni), chromium (Cr), chrome nitride (CrN), titanium (Ti), tantalum (Ta), platinum (Pt), scandium (Sc), indium tin oxide (ITO), or indium zinc oxide (IZO). The bottom metal layer BML may have a multilayer structure. For example, the bottom metal layer BML may have a two-layer structure of Mo/Al or Ti/Al, or may have a three-layer structure of Mo/Al/Mo or Ti/Al/Ti.

As illustrated in FIG. 5, the bottom metal layer BML may include the initialization-sensing line ISL, the power line PL, a blue data line DLb, a green data line DLg, a red data line DLr, and first auxiliary capacitor electrodes Cst1r′, Cst1g′, and Cst1b′. Each of the initialization-sensing line ISL, the power line PL, the blue data line DLb, the green data line DLg, and the red data line DLr may have a shape extending in a first direction (a y-axis direction), and each of the first auxiliary capacitor electrodes Cst1r′, Cst1g′, and Cst1b′ may have an isolated shape. The initialization-sensing line ISL, the power line PL, the red data line DLr, the green data line DLg, and the blue data line DLb may be sequentially arranged in a second direction (an x-axis direction) crossing (intersecting) the first direction. The first auxiliary capacitor electrodes Cst1r′, Cst1g′, and Cst1b′ may be located between the power line PL and the red, greed, and blue data lines DLr, DLg, and DLb.

The initialization-sensing line ISL may extend in the first direction (the y-axis direction), as described above. The initialization-sensing line ISL may be electrically connected to a first portion of each of the third transistors T3r, T3g, and T3b, which are initialization-sensing transistors, so that in case the third transistors T3r, T3g, and T3b are turned on, the initialization-sensing signal ISS from the initialization-sensing line ISL may be transmitted to a red pixel electrode PEr, a green pixel electrode PEg, or a blue pixel electrode PEb.

The power line PL may also extend in the first direction (the y-axis direction), as described above. The power line PL may be electrically connected to each of the first transistors T1r, T1g, and T1b, which are driving transistors, so that the driving power voltage ELVDD may be applied to the first transistors T1r, T1g, and T1b.

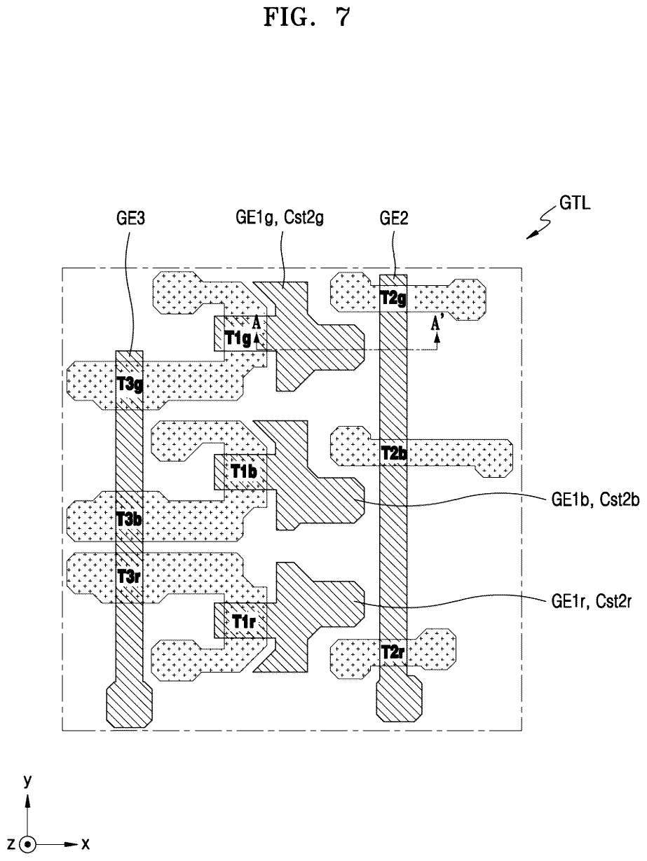

Each of the red data line DLr, the green data line DLg, and the blue data line DLb may also extend in the first direction (the y-axis direction). The red data line DLr may be electrically connected to a first portion of the second transistor T2r of the red subpixel, the green data line DLg may be electrically connected to a first portion of the second transistor T2g of the green subpixel, and the blue data line DLb may be electrically connected to a first portion of the second transistor T2b of the blue subpixel. In case that the second transistor T2r of the red subpixel, the second transistor T2g of the green subpixel, and the second transistor T2b of the blue subpixel are turned on by a second gate electrode GE2 (see FIG. 7) electrically connected to the scan line SL (see FIG. 8), the second transistor T2r of the red subpixel, the second transistor T2g of the green subpixel, and the second transistor T2b of the blue subpixel may transmit data signals DATA from the red data line DLr, the green data line DLg, and the blue data line DLb to a first gate electrode GE1r (see FIG. 7), which is a driving gate electrode of the first transistor T1r of the red subpixel, a first gate electrode GE1g (see FIG. 7), which is a driving gate electrode of the first transistor T1g of the green subpixel, and a first gate electrode GE1b (see FIG. 7), which is a driving gate electrode of the first transistor T1b of the blue subpixel.

Each of the first auxiliary capacitor electrodes Cst1r′, Cst1g′, and Cst1b′ may be electrically connected to a corresponding one of the first capacitor electrodes Cst1r, Cst1g, and Cst1b (see FIG. 8) and may serve as one capacitor electrode of the storage capacitor Cst.

A second buffer layer 102 (see FIG. 11) may be arranged on the first buffer layer 101 to cover the bottom metal layer BML. The second buffer layer 102 may include an insulating material. For example, the second buffer layer 102 may include an inorganic insulating material, such as silicon oxide, silicon nitride, silicon oxynitride, or aluminum oxide.

The active layer ACT as illustrated in FIG. 6 may be disposed over the second buffer layer 102. The active layer ACT may include a semiconductor material, for example, polysilicon or an oxide semiconductor. The oxide semiconductor may include a Zn oxide-based material, for example, Zn oxide, In—Zn oxide, or Ga—In—Zn oxide. In other embodiments, the oxide semiconductor may include In—Ga—Zn—O (IGZO), In—Sn—Zn—O (ITZO), or In—Ga—Sn—Zn—O (IGTZO), each containing a metal, such as indium (In), gallium (Ga), or tin (Sn), in zinc oxide (ZnO). Hereinafter, for convenience, a case where the active layer ACT includes an oxide semiconductor is described.

The active layer ACT may include a first active layer ACT1 and a second active layer ACT2. In each of the red subpixel, the green subpixel, and the blue subpixel, the first active layer ACT1 and the second active layer ACT2 may be spaced apart from each other.

The first active layers ACT1 may be components of the first transistors T1r, T1g, and T1b, which are driving transistors, and may be components of the third transistors T3r, T3g, and T3b, which are initialization-sensing transistors.

Each of the second active layers ACT2 may have a shape extending in the second direction (the x-axis direction) so as to cross a portion of the second gate electrode GE2 that is electrically connected to the scan line SL and extends in the first direction (the y-axis direction). For example, the second active layers ACT2 may be components of the second transistors T2r, T2g, and T2b, which are switching transistors. A first portion of each of the second active layers ACT2 that is located in a direction toward the red, greed, and blue data lines DLr, DLg, and DLb may be electrically connected to a corresponding one of the red, greed, and blue data lines DLr, DLg, and DLb through a corresponding one of data connection lines DCLr, DCLg, and DCLb (see FIG. 8).

A gate insulating layer 104 (see FIG. 11) may be arranged on the second buffer layer 102 to cover the active layer ACT. The gate insulating layer 104 may include an insulating material. For example, the gate insulating layer 104 may include an inorganic insulating material, such as silicon oxide, silicon nitride, silicon oxynitride, or aluminum oxide.

A gate layer GTL as illustrated in FIG. 7 may be arranged on the gate insulating layer 104. For convenience, FIG. 7 illustrates the gate layer GTL together with the active layer ACT located below the gate layer GTL. The gate layer GTL may include the first gate electrodes GE1r, GE1g, and GE1b, which are driving gate electrodes, the second gate electrode GE2, and a third gate electrode GE3.

The first gate electrode GE1r may be a component of the first transistor T1r of the red subpixel, the first gate electrode GE1g may be a component of the first transistor T1g of the green subpixel, and the first gate electrode GE1b may be a component of the first transistor T1b of the blue subpixel. Each of the first gate electrodes GE1r, GE1g, and GE1b may have an isolated shape and may overlap a portion of a corresponding one of the first active layers ACT1.

The first gate electrodes GE1r, GE1g, and GE1b may be gate electrodes of the first transistors T1r, T1g, and T1b and may simultaneously be second capacitor electrodes Cst2r, Cst2g, and Cst2b of the storage capacitors Cst. Accordingly, each of the first gate electrodes GE1r, GE1g, and GE1b may overlap a portion of a corresponding one of the first active layers ACT1 and may also overlap a corresponding one of the first auxiliary capacitor electrodes Cst1r′, Cst1g′, and Cst1b′. FIGS. 4, 5, and 7 illustrate that each of the first gate electrodes GE1r, GE1g, and GE1b is located within a corresponding one of the first auxiliary capacitor electrodes Cst1r′, Cst1g′, and Cst1b′ in the plan view.

The second gate electrode GE2, which is formed as a single body, may have a shape extending approximately in the first direction (the y-axis direction) and may overlap each of the second active layer ACT2 of the red subpixel, the second active layer ACT2 of the green subpixel, and the second active layer ACT2 of the blue subpixel. The second gate electrode GE2 may be electrically connected to the scan line SL (see FIG. 8) above the second gate electrode GE2 through a contact hole and may serve as a common gate electrode of the second transistors T2r, T2g, and T2b, which are switching transistors.

The third gate electrode GE3, which is formed as a single body, may also have a shape extending approximately in the first direction (the y-axis direction) and may overlap each of the first active layer ACT1 of the red subpixel, the first active layer ACT1 of the green subpixel, and the first active layer ACT1 of the blue subpixel. The third gate electrode GE3 may be electrically connected to the scan line SL (see FIG. 8) above the third gate electrode GE3 through a contact hole and may serve as a common gate electrode of the third transistors T3r, T3g, and T3b, which are initialization-sensing transistors.

The gate layer GTL may include a metal, an alloy, a conductive metal oxide, or a transparent conductive material. For example, the gate layer GTL may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The gate layer GTL may have a multilayer structure. For example, the gate layer GTL may have a two-layer structure of Mo/Al or Ti/Al, or may have a three-layer structure of Mo/Al/Mo or Ti/Al/Ti.

As described above, for convenience, FIG. 7 illustrates the gate layer GTL together with the active layer ACT. Thus, impurities may be added to a portion of the active layer ACT that does not overlap the gate layer GTL. For example, the portion of the active layer ACT that does not overlap the gate layer GTL may be a doped portion. Accordingly, electrical characteristics of the portion of the active layer ACT that does not overlap the gate layer GTL may be different from electrical characteristics of a portion of the active layer ACT that overlaps the gate layer GTL. In detail, resistance of the portion of the active layer ACT that does not overlap the gate layer GTL may be lower than resistance of the portion of the active layer ACT that overlaps the gate layer GTL in case that a channel is not formed in the portion. Because such a low-resistance portion may function as a conductor, the portion of the active layer ACT that does not overlap the gate layer GTL may be a source region or drain region and may simultaneously serve as a wiring.

A first interlayer insulating film 105 (see FIG. 11) may be arranged on the gate insulating layer 104 to cover the gate layer GTL. The first interlayer insulating film 105 may include an insulating material. For example, the first interlayer insulating film 105 may include an inorganic insulating material, such as silicon oxide, silicon nitride, silicon oxynitride, or aluminum oxide.

A first source-drain layer SDL1 as illustrated in FIG. 8 may be arranged on the first interlayer insulating film 105. The first source-drain layer SDL1 may include the data connection lines DCLr, DCLg, and DCLb, transistor connection layers TCL, the first capacitor electrodes Cst1r, Cst1g, and Cst1b, a power connection line PCL, an initialization-sensing connection line ICL, and the scan line SL. Each of the data connection lines DCLr, DCLg, and DCLb, the transistor connection layers TCL, and the first capacitor electrodes Cst1r, Cst1g, and Cst1b may have an isolated shape. Each of the power connection line PCL and the initialization-sensing connection line ICL may have a shape extending in the first direction (the y-axis direction) and may ultimately have an isolated shape. The scan line SL may have a shape extending in the second direction (the x-axis direction) and may pass through multiple pixels.

The scan line SL may extend approximately in the second direction (the x-axis direction), may contact the second gate electrode GE2 below the scan line SL through a first contact hole CT1, and may contact the third gate electrode GE3 below the scan line SL through a second contact hole CT2. As described above, the first active layer ACT1 may have a shape extending in the second direction (the x-axis direction) so as to cross a portion of the third gate electrode GE3 that is electrically connected to the scan line SL, and the second active layer ACT2 may also have a shape extending in the second direction (the x-axis direction) so as to cross a portion of the second gate electrode GE2 that is electrically connected to the scan line SL. Accordingly, the second transistors T2r, T2g, and T2b and the third transistors T3r, T3g, and T3b may be turned on or off by electrical signals from the scan line SL.

The initialization-sensing connection line ICL may be electrically connected to the initialization-sensing line ISL below the initialization-sensing connection line ICL through a third contact hole CT3 and may be electrically connected to a first portion of the first active layer ACT1 below the initialization-sensing connection line ICL through a fourth contact hole CT4. The first portion of the first active layer ACT1 may be a portion of the first active layer ACT1 that is located in a direction toward the initialization-sensing line ISL with respect to the third gate electrode GE3. Accordingly, the initialization-sensing line ISL may be electrically connected to the first portion of the first active layer ACT1 through the initialization-sensing connection line ICL. The initialization-sensing connection line ICL may extend in the first direction (the y-axis direction) and pass through not only the green subpixel but also the red and blue subpixels. Thus, the initialization-sensing connection line ICL may be electrically connected to the first portion of the first active layer ACT1 of the red subpixel below the initialization-sensing connection line ICL and the first portion of the first active layer ACT1 of the blue subpixel below the initialization-sensing connection line ICL through the fourth contact hole CT4 present at a location corresponding to the red subpixel and the fourth contact hole CT4 present at a location corresponding to the blue subpixel, respectively.

The first capacitor electrode Cst1g may be electrically connected to a second portion of the first active layer ACT1 below the first capacitor electrode Cst1g through a fifth contact hole CT5 and may be electrically connected to the first auxiliary capacitor electrode Cst1g′ below the first capacitor electrode Cst1g through a sixth contact hole CT6. The first gate electrode GE1g, which is the second capacitor electrode Cst2g, may be located between the first auxiliary capacitor electrode Cst1g′ and the first capacitor electrode Cst1g. Accordingly, the first capacitor electrode Cst1g and the first gate electrode GE1g may form the storage capacitor Cst. The second portion of the first active layer ACT1 may be a portion of the first active layer ACT1 that is located in a direction away from the initialization-sensing line ISL with respect to the third gate electrode GE3. The first capacitor electrode Cst1g may correspond to the second node N2 in the pixel circuit PC of FIG. 3. The above description may also be applied to the first capacitor electrode Cst1r in the red subpixel and the first capacitor electrode Cst1b in the blue subpixel.

The data connection line DCLg may be electrically connected to a first portion of the second active layer ACT2 below the data connection line DCLg through an eighth contact hole CT8 and may be electrically connected to the green data line DLg below the data connection line DCLg through a seventh contact hole CT7. The first portion of the second active layer ACT2 may be a portion of the second active layer ACT2 that is located in a direction toward the green data line DLg with respect to the second gate electrode GE2. The above description may also be applied to the data connection line DCLr in the red subpixel and the data connection line DCLb in the blue subpixel.

The transistor connection layer TCL may be electrically connected to a second portion of the second active layer ACT2 below the transistor connection layer TCL through a ninth contact hole CT9 and may be electrically connected to the first gate electrode GE1g below the transistor connection layer TCL, which is the second capacitor electrode Cst2g, through a tenth contact hole CT10. The second portion of the second active layer ACT2 may be a portion of the second active layer ACT2 that is located in a direction away from the green data line DLg with respect to the second gate electrode GE2. However, the second portion of the second active layer ACT2 may be referred to as a portion of the second active layer ACT2 in the −y direction with respect to a portion of the first gate electrode GE1g that protrudes onto the second active layer ACT2. The transistor connection layer TCL may correspond to the first node N1 in the pixel circuit PC of FIG. 3. The above description may also be applied to the transistor connection layer TCL in the red subpixel and the transistor connection layer TCL in the blue subpixel.

The power connection line PCL may be electrically connected to the power line PL below the power connection line PCL through an eleventh contact hole CT11 and may be electrically connected to a third portion of the first active layer ACT1 below the power connection line PCL through a twelfth contact hole CT12. The third portion of the first active layer ACT1 may be referred to as a portion of the first active layer ACT1 in the +y direction with respect to a portion of the first gate electrode GE1g that protrudes onto the first active layer ACT1. Accordingly, in case that the first transistor T1 is turned on, current may flow from the power line PL to the third portion of the first active layer ACT1 through the power connection line PCL. The power connection line PCL may extend in the first direction (the y-axis direction) and pass through not only the green subpixel but also the red and blue subpixels. Thus, the power connection line PCL may be electrically connected to the third portion of the first active layer ACT1 of the red subpixel below the power connection line PCL and the third portion of the first active layer ACT1 of the blue subpixel below the power connection line PCL through the twelfth contact hole CT12 present at a location corresponding to the red subpixel and the twelfth contact hole CT12 present at a location corresponding to the blue subpixel, respectively.

The first source-drain layer SDL1 may include a metal, an alloy, a conductive metal oxide, or a transparent conductive material. For example, the first source-drain layer SDL1 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The first source-drain layer SDL1 may have a multilayer structure. For example, the first source-drain layer SDL1 may have a two-layer structure of Mo/Al or Ti/Al, or may have a three-layer structure of Mo/Al/Mo or Ti/Al/Ti.

A second interlayer insulating film 106 (see FIG. 11) may be arranged on the first interlayer insulating film 105 to cover the first source-drain layer SDL1. The second interlayer insulating film 106 may include an insulating material. For example, the second interlayer insulating film 106 may include an inorganic insulating material, such as silicon oxide, silicon nitride, silicon oxynitride, or aluminum oxide. In some embodiments, the second layer insulating film 106 may also include an organic insulating material. The organic insulating material may include a photoresist, benzocyclobutene (BCB), polyimide, hexamethyldisiloxane (HMDSO), polymethylmethacrylate (PMMA), polystyrene, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a mixture thereof.

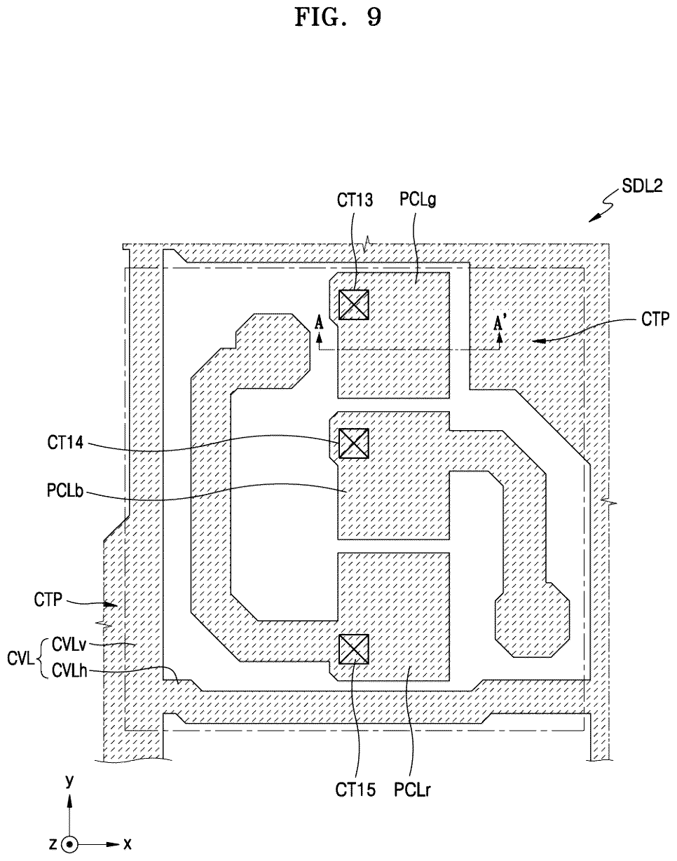

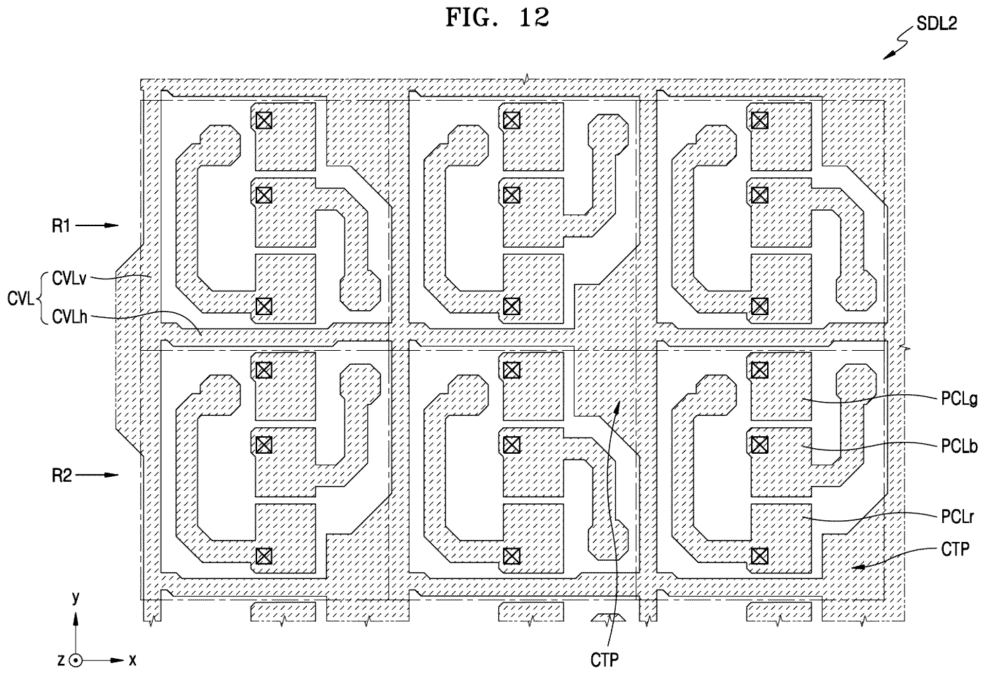

A second source-drain layer SDL2 as illustrated in FIG. 9 may be arranged on the second interlayer insulating film 106. The second source-drain layer SDL2 may include pixel electrode connection layers PCLr, PCLg, and PCLb and the common voltage line CVL. Each of the pixel electrode connection layers PCLr, PCLg, and PCLb may have an isolated shape. The common voltage line CVL may include a portion CVLv extending in the first direction (the y-axis direction) and a portion CVLh extending in the second direction (the x-axis direction) and may pass through multiple pixels. In detail, the portion CVLv of the common voltage line CVL that extends in the first direction (the y-axis direction) and the portion CVLh of the common voltage line CVL that extends in the second direction (the x-axis direction) may be integrally formed as a single body (integral with each other), and thus, the common voltage line CVL may have a mesh shape in the plan view. FIG. 12 is a schematic plan view illustrating the second source-drain layer SDL2 in multiple pixels and illustrates that the common voltage line CVL has a mesh shape.

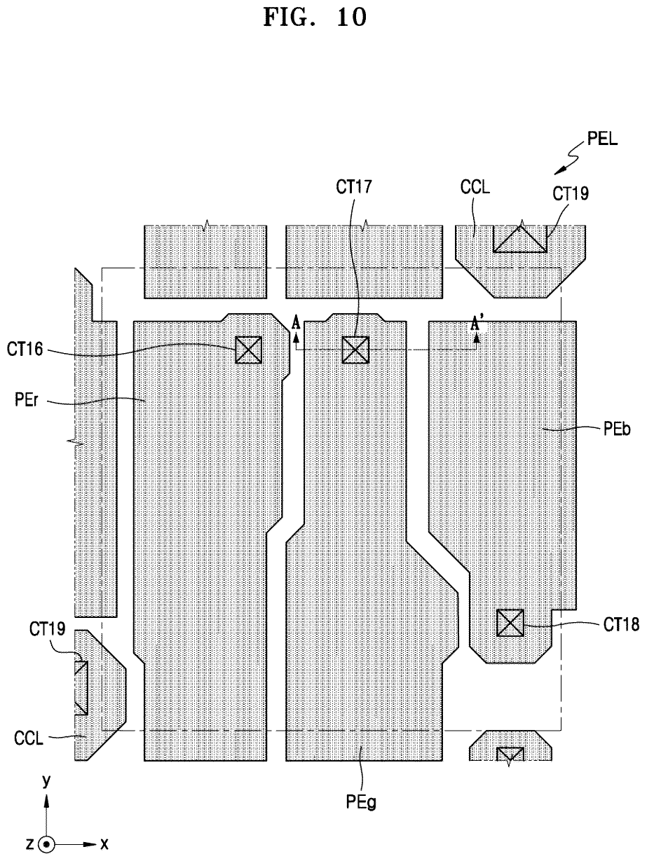

The pixel electrode connection layer PCLg may be electrically connected to the first capacitor electrode Cst1g below the pixel electrode connection layer PCLg through a thirteenth contact hole CT13. The pixel electrode connection layer PCLg may be electrically connected to the green pixel electrode PEg (see FIG. 10) above the pixel electrode connection layer PCLg so that current of an amount determined by the first transistor T1 may flow from the power line PL to the green pixel electrode PEg.

The above description may also be applied to the pixel electrode connection layer PCLr in the red subpixel and the pixel electrode connection layer PCLb in the blue subpixel. For example, the pixel electrode connection layer PCLb may be electrically connected to the first capacitor electrode Cst1b below the pixel electrode connection layer PCLb through a fourteenth contact hole CT14, and the pixel electrode connection layer PCLr may be electrically connected to the first capacitor electrode Cst1r below the pixel electrode connection layer PCLr through a fifteenth contact hole CT15. However, unlike the pixel electrode connection layer PCLg, each of the pixel electrode connection layer PCLr and the pixel electrode connection layer PCLb may have a protrusion in the plan view, as illustrated in FIG. 9. This is to secure a location where the red pixel electrode PEr is to be connected to the pixel electrode connection layer PCLr and a location where the blue pixel electrode PEb is to be connected to the pixel electrode connection layer PCLb.

The pixel electrode connection layers PCLr, PCLg, and PCLb may be located within the common voltage line CVL having a mesh shape in the plan view. For example, the pixel electrode connection layers PCLr, PCLg, and PCLb may be located within an empty space of the common voltage line CVL having a mesh shape.

A pixel electrode connection layer may overlap the transistor connection layer TCL below the pixel electrode connection layer in the plan view. FIGS. 4, 8, and 9 illustrate that the transistor connection layer TCL of the green subpixel is located within the pixel electrode connection layer PCLg in the plan view. This also may apply to the red subpixel and the blue subpixel.

As described above, the transistor connection layer TCL may correspond to the first node N1 in the pixel circuit PC of FIG. 3. A voltage of the first node N1 may be a voltage of the driving gate electrode of the first transistor T1, and the first transistor T1 may control the amount of current flowing from the power line PL to the organic light-emitting diode OLED, in response to the voltage of the first node N1. Accordingly, it may be desirable to protect the first node N1 from the outside. In the display apparatus 1 according to the embodiment, because a pixel electrode connection layer overlaps the transistor connection layer TCL below the pixel electrode connection layer in the plan view, the pixel electrode connection layer may shield the transistor connection layer TCL, which is the first node N1. Accordingly, a display apparatus that displays a high-quality image may be implemented.

For the above structure, the pixel electrode connection layers PCLr, PCLg, and PCLb in one pixel may be arranged in the first direction (the y-axis direction), as illustrated in FIGS. 9 and 12. This is because the transistor connection layer TCL of the red subpixel, the transistor connection layer TCL of the green subpixel, and the transistor connection layer TCL of the blue subpixel may be arranged in the first direction (the y-axis direction). FIG. 9 and FIG. 12 illustrate that the pixel electrode connection layer PCLg, the pixel electrode connection layer PCLb, and the pixel electrode connection layer PCLr are sequentially arranged in the first direction (the y-axis direction).

Each of the first gate electrodes GE1r, GE1g, and GE1b, which is electrically connected to the transistor connection layer TCL through the tenth contact hole CT10, may also be referred to as the first node N1. In the green subpixel, the first gate electrode GE1g may be located within a set of the first capacitor electrode Cst1g and the pixel electrode connection layer PCLg in the plan view. Accordingly, the set of the first capacitor electrode Cst1g and the pixel electrode connection layer PCLg may shield the first gate electrode GE1g. This also may apply to the red subpixel and the blue subpixel.

The second source-drain layer SDL2 may include a metal, an alloy, a conductive metal oxide, or a transparent conductive material. For example, the second source-drain layer SDL2 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The second source-drain layer SDL2 may have a multilayer structure. For example, the second source-drain layer SDL2 may have a two-layer structure of Mo/Al or Ti/Al, or may have a three-layer structure of Mo/Al/Mo or Ti/Al/Ti.

A planarization layer 107 (see FIG. 11) may be disposed over the second interlayer insulating film 106 to cover the second source-drain layer SDL2. The planarization layer 107 may include an organic insulating material. For example, the planarization layer 107 may include a photoresist, BCB, polyimide, HMDSO, PMMA, polystyrene, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a mixture thereof.

A pixel electrode layer PEL as illustrated in FIG. 10 may be disposed over a planarization layer 107. The pixel electrode layer PEL may include a common electrode connection layer CCL, the red pixel electrode PEr, the green pixel electrode PEg, and the blue pixel electrode PEb. Each of the common electrode connection layer CCL, the red pixel electrode PEr, the green pixel electrode PEg, and the blue pixel electrode PEb may have an isolated shape.

The pixel electrode layer PEL may be a (semi-) light-transmissive electrode layer or a reflective electrode layer. For example, the pixel electrode layer PEL may include a reflective layer including Ag, Mg, Al, Pt, Pd, Au, Ni, Nd, Ir, Cr, and a compound thereof, and a transparent or semi-transparent electrode layer disposed over the reflective layer. The transparent or semi-transparent electrode layer may include at least one selected from among ITO, IZO, ZnO, indium oxide (In₂O₃), indium gallium oxide (IGO), and aluminum zinc oxide (AZO). For example, the pixel electrode layer PEL may have a three-layer structure of ITO/Ag/ITO.

The red pixel electrode PEr may be electrically connected to the pixel electrode connection layer PCLr below the red pixel electrode PEr through a sixteenth contact hole CT16. The green pixel electrode PEg may be electrically connected to the pixel electrode connection layer PCLg below the green pixel electrode PEg through a seventeenth contact hole CT17. The blue pixel electrode PEb may be electrically connected to the pixel electrode connection layer PCLb below the blue pixel electrode PEb through an eighteenth contact hole CT18.

The red pixel electrode PEr, the green pixel electrode PEg, and the blue pixel electrode PEb may be sequentially arranged in the second direction (the x-axis direction). Accordingly, each of the pixel electrode connection layer PCLr and the pixel electrode connection layer PCLb, which correspond to the red pixel electrode PEr located on the left and the blue pixel electrode PEb located on the right, may have a protrusion in the plan view. This is to secure a location where the red pixel electrode PEr is to be connected to the pixel electrode connection layer PCLr and a location where the blue pixel electrode PEb is to be connected to the pixel electrode connection layer PCLb. For example, because the red pixel electrode PEr in one pixel is located on the left side of the pixel, the pixel electrode connection layer PCLr may have a protrusion at a location corresponding to the sixteenth contact hole CT16, which is also located on the left side of the pixel. Likewise, because the blue pixel electrode PEb in one pixel is located on the right side of the pixel, the pixel electrode connection layer PCLb may have a protrusion at a location corresponding to the eighteenth contact hole CT18, which is also located on the right side of the pixel.

The common electrode connection layer CCL may be electrically connected to the common voltage line CVL below the common electrode connection layer CCL through a nineteenth contact hole CT19. To this end, the common voltage line CVL may have a contact portion CTP, as illustrated in FIG. 9. The common voltage line CVL may have the contact portion CTP in a portion where the portion CVLv of the common voltage line CVL that extends in the first direction (the y-axis direction) meets the portion CVLh of the common voltage line CVL that extends in the second direction (the x-axis direction).

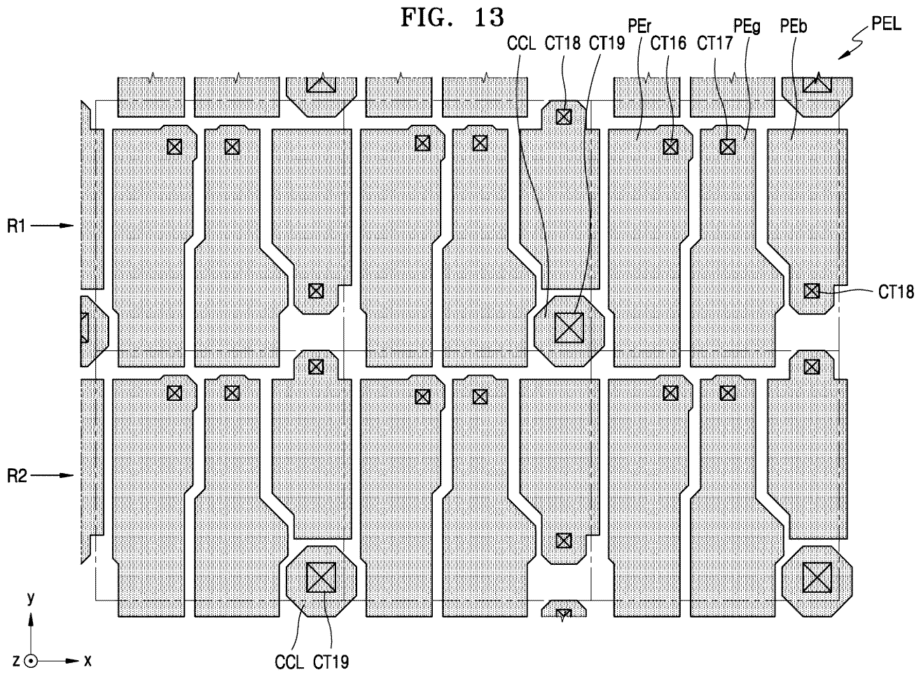

As illustrated in FIG. 9, the common voltage line CVL may have one contact portion CTP per one pixel including a red subpixel, a green subpixel, and a blue subpixel. In contrast, the pixel electrode layer PEL may not have a common electrode connection layer CCL corresponding to all pixels. FIG. 13 is a schematic plan view illustrating the pixel electrode layer PEL in multiple pixels and illustrates that one common electrode connection layer CCL is present per two pixels. Accordingly, by expanding the area occupied by the red, green, and blue pixel electrodes PEr, PEg, and PEb in the pixel electrode layer PEL, a display apparatus that displays a high-quality image may be implemented.

A pixel-defining film 109 may be arranged on the planarization layer 107. The pixel-defining film 109 may have openings to expose a central portion of each of the red pixel electrode PEr, the green pixel electrode PEg, and the blue pixel electrode PEb, while covering an edge of each of the red pixel electrode PEr, the green pixel electrode PEg, and the blue pixel electrode PEb. Accordingly, the pixel-defining film 109 may increase a distance between the edge of each of the red pixel electrode PEr, the green pixel electrode PEg, and the blue pixel electrode PEb and a common electrode CE above the pixel-defining film, thus preventing arcs or the like from occurring at the edges of the red pixel electrode PEr, the green pixel electrode PEg, and the blue pixel electrode PEb.

The pixel-defining film 109 may also have through holes. Accordingly, at least a portion of each of the common electrode connection layers CCL disposed over the planarization layer 107 may be exposed by a corresponding one of the through holes. The common electrode CE may be electrically connected to the common electrode connection layers CCL through the through holes. As a result, the common electrode CE may be electrically connected to the common voltage line CVL through the common electrode connection layers CCL.

The pixel-defining film 109 may include at least one organic insulating material selected from among polyimide, polyamide, acrylic resin, BCB, and phenolic resin and may be formed by a method such as spin coating.

The common electrode CE may be a light-transmissive electrode or a reflective electrode. For example, the common electrode CE may be a transparent or semi-transparent electrode and may include a metal thin film including Li, Ca, LiF, Al, Ag, Mg, and a compound thereof and having a low work function. Also, the common electrode CE may further include a transparent conductive oxide (TCO) film, such as ITO, IZO, ZnO, or In₂O₃, disposed on the metal thin film. The common electrode CE may be formed as a single body over the entire surface of the display area DA and may be arranged above multiple pixel electrodes.

An intermediate layer may be located between a pixel electrode and the common electrode CE, and at least a portion of the intermediate layer may be located within an opening on the pixel electrode, which is formed by the pixel-defining film 109. An emission area of the organic light-emitting diode OLED may be defined by the opening. The intermediate layer may include an emission layer. The emission layer may include an organic material including a fluorescent or phosphorescent material that emits red, green, blue, or white light. The emission layer may include a low-molecular weight organic material or a polymer organic material, and functional layers, such as a hole transport layer (HTL), a hole injection layer (HIL), an electron transport layer (ETL), and an electron injection layer (EIL), may be optionally arranged below and above the emission layer.

The emission layer may have a patterned shape corresponding to each pixel electrode. A layer other than the emission layer included in the intermediate layer may be variously modified. For example, the layer may be integrally formed as a single body throughout multiple pixel electrodes.

In a manufacturing process, the pixel-defining film 109 having openings exposing pixel electrodes may be formed, the intermediate layer including an emission layer may be formed, and through holes may be formed in the pixel-defining film 109. In forming the through holes in the pixel-defining film 109, a portion of the intermediate layer disposed on the pixel-defining film 109 may also be removed so that the common electrode CE formed thereafter may contact the common electrode connection layers CCL through the through holes. The through holes may be formed, for example, through a laser drilling method in which a laser beam is irradiated to the pixel-defining film 109 and the irradiated portion of the pixel-defining film 109 is removed.

The second source-drain layer SDL2 may not have the common voltage line CVL having a mesh shape and may have first common voltage lines having a line shape extending in any one of the first direction (the y-axis direction) and the second direction (the x-axis direction). The pixel electrode layer PEL may have second common voltage lines having a line shape extending in another direction so that the first common voltage lines and the second common voltage lines may be electrically connected to each other through contact holes. However, the area of the red, green, and blue pixel electrodes PEr, PEg, and PEb in the pixel electrode layer PEL may be reduced, and thus, a high-quality image may not be displayed, or power consumption may increase.

In the display apparatus 1 according to the embodiment, because the second source-drain layer SDL2 has the common voltage line CVL having a mesh shape, the area of the red, green, and blue pixel electrodes PEr, PEg, and PEb may be sufficiently secured, and thus, the occurrence of the above issues may be prevented or reduced. Also, as described above with reference to FIG. 13, because one common electrode connection layer CCL is present per multiple pixels, the area occupied by the red, green, and blue pixel electrodes PEr, PEg, and PEb in the pixel electrode layer PEL may be further expanded. FIG. 13 illustrates that, in pixels located in a first row R1 extending in the second direction (the x-axis direction), the common electrode connection layers CCL are located to correspond to odd-numbered pixels, and in pixels located in a second row R2 adjacent to the first row R1 and extending in the second direction (the x-axis direction), the common electrode connection layers CCL are located to correspond to even-numbered pixels.

As illustrated in FIGS. 10 and 13, in the blue subpixel, the blue pixel electrode PEb may have a first end adjacent to a corresponding one of the common electrode connection layers CCL and a second end facing away from the corresponding one of the common electrode connection layers CCL, and the eighteenth contact hole CT18 through which the blue pixel electrode PEb contacts the pixel electrode connection layer PCLb below the blue pixel electrode PEb may be located at the second end of the blue pixel electrode PEb. Accordingly, in blue subpixels on an imaginary line extending in the second direction (the x-axis direction), for example, in blue subpixels of the first row R1, locations of the eighteenth contact holes CT18 may alternate between the +y direction and the −y direction. This may be due to the arrangement of the common electrode connection layers CCL as described above.

As described above with reference to FIG. 9, the common electrode connection layer CCL may have the contact portion CTP in each pixel. As illustrated in FIG. 12, two adjacent contact portions CTP in two pixels which are adjacent to each other in the first direction (the y-axis direction) may be recognized as one contact portion. In this manner, because the area of the two contact portions CTP, which is recognized as one contact portion, is sufficiently large, the common voltage line CVL and the common electrode connection layer CCL may contact each other over a sufficiently large area, and the common electrode connection layer CCL and the common electrode CE may also contact each other over a sufficiently large area.

According to one or more embodiments as described above, a display apparatus in which a high-quality image may be displayed with a high aperture ratio may be implemented. However, the scope of the disclosure is not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. A display apparatus, comprising:
a bottom metal layer including a power line and a data line each of which extends in a first direction;
an active layer disposed over the bottom metal layer and including a semiconductor material;
a gate layer disposed over the active layer and including gate electrodes each of which overlaps a portion of the active layer;
a first source-drain layer disposed over the gate layer and including a scan line extending in a second direction intersecting the first direction;
a second source-drain layer disposed over the first source-drain layer and including a common voltage line having a portion extending in the first direction and a portion extending in the second direction; and
a pixel electrode layer disposed over the second source-drain layer and including a pixel electrode.

2. The display apparatus of claim 1, wherein the portion of the common voltage line which extends in the first direction and the portion of the common voltage line which extends in the second direction are integral with each other.

3. The display apparatus of claim 1, wherein the common voltage line has a mesh shape in a plan view.

4. The display apparatus of claim 3, wherein
the active layer includes a first active layer and a second active layer which are spaced apart from each other,
the gate electrodes include a first gate electrode and a second gate electrode, the first gate electrode overlapping a portion of the first active layer, and the second gate electrode extending in the first direction and overlapping a portion of the second active layer,
the first source-drain layer includes a transistor connection layer and a capacitor electrode, the transistor connection layer electrically connecting the second active layer and the first gate electrode to each other, and the capacitor electrode overlapping the first gate electrode, and
the second source-drain layer includes a pixel electrode connection layer located within the common voltage line having the mesh shape in the plan view.

5. The display apparatus of claim 4, wherein the pixel electrode connection layer overlaps the transistor connection layer in the plan view.

6. The display apparatus of claim 4, wherein the transistor connection layer is located within the pixel electrode connection layer in the plan view.

7. The display apparatus of claim 4, wherein the first gate electrode is located within a set of the capacitor electrode and the pixel electrode connection layer in the plan view.

8. The display apparatus of claim 4, wherein the pixel electrode connection layer is electrically connected to the capacitor electrode.

9. The display apparatus of claim 8, wherein the first gate electrode is located within a set of the capacitor electrode and the pixel electrode connection layer in the plan view.

10. The display apparatus of claim 4, wherein the pixel electrode connection layer contacts the capacitor electrode through a contact hole.

11. The display apparatus of claim 10, wherein the first gate electrode is located within a set of the capacitor electrode and the pixel electrode connection layer in the plan view.

12. The display apparatus of claim 4, wherein the pixel electrode contacts the pixel electrode connection layer through a contact hole.

13. The display apparatus of claim 3, wherein the pixel electrode layer includes common electrode connection layers each of which is electrically connected to the common voltage line.

14. The display apparatus of claim 13, wherein each of the common electrode connection layers contacts the common voltage line through a contact hole.

15. The display apparatus of claim 13, wherein the common electrode connection layers contact a common electrode disposed over the pixel electrode.

16. The display apparatus of claim 15, wherein the common electrode connection layers correspond to through holes defined in a pixel-defining film covering an edge of the pixel electrode.

17. The display apparatus of claim 13, wherein, in pixels located in a first row extending in the second direction, the common electrode connection layers are located to correspond to odd-numbered pixels.

18. The display apparatus of claim 17, wherein
the second source-drain layer includes a pixel electrode connection layer, and
in a blue subpixel, the pixel electrode has a first end adjacent to a corresponding one of the common electrode connection layers and a second end facing away from the corresponding one of the common electrode connection layers, a contact hole through which the pixel electrode contacts the pixel electrode connection layer being located at the second end.

19. The display apparatus of claim 17, wherein, in pixels located in a second row adjacent to the first row and extending in the second direction, the common electrode connection layers are located to correspond to even-numbered pixels.

20. The display apparatus of claim 19, wherein
the second source-drain layer includes a pixel electrode connection layer, and
in a blue subpixel, the pixel electrode has a first end adjacent to a corresponding one of the common electrode connection layers and a second end facing away from the corresponding one of the common electrode connection layers, a contact hole through which the pixel electrode contacts the pixel electrode connection layer being located at the second end.
